(19) United States
(12) Patent Application Publication
(10) Pub. No.: US 2025/0246865 A1
(43) Pub. Date: Jul. 31, 2025

(54) LASER APPARATUS AND ELECTRONIC DEVICE MANUFACTURING METHOD

(71) Applicant: Gigaphoton Inc., Tochigi (JP)

(72) Inventor: Takahito KUMAZAKI, Oyama-shi (JP)

(73) Assignee: Gigaphoton Inc., Tochigi (JP)

(21) Appl. No.: 18/965,547

(22) Filed: Dec. 2, 2024

(30) Foreign Application Priority Data
Jan. 31, 2024 (JP) 2024-013668

(51) Int. Cl. H01S 3/08; G03F 7/00

(52) U.S. Cl. CPC H01S 3/08009; G03F 7/70025

(57) ABSTRACT

A laser apparatus according to one aspect of the present disclosure includes a line narrowing module and an output coupling mirror. The line narrowing module includes a prism including a transmission surface through which a laser beam is transmitted, a bottom surface in contact with the transmission surface, and a top surface facing the bottom surface, and a holder holding the prism on the bottom surface. The output coupling mirror includes a partial reflective film having a reflectance changing in a direction in which the bottom surface and the top surface face each other.

### CROSS-REFERENCE TO RELATED APPLICATIONS

The present application claims the benefit of Japanese Patent Application No. 2024-013668, filed on Jan. 31, 2024, the entire contents of which are hereby incorporated by reference.

### BACKGROUND

### 1. Technical Field

The present disclosure relates to a laser apparatus and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: U.S. Pat. No. 7,903,700

Patent Document 2: Japanese Patent No. 3638110

Patent Document 3: Japanese Patent No. 3591360

### SUMMARY

A laser apparatus according to one aspect of the present disclosure includes a line narrowing module and an output coupling mirror. The line narrowing module includes a prism including a transmission surface through which a laser beam is transmitted, a bottom surface in contact with the transmission surface, and a top surface facing the bottom surface, and a holder holding the prism on the bottom surface. The output coupling mirror includes a partial reflective film having a reflectance changing in a direction in which the bottom surface and the top surface face each other.

An electronic device manufacturing method according to one aspect of the present disclosure includes generating a laser beam with a laser apparatus, outputting the laser beam to an exposure apparatus, and exposing a photosensitive substrate to the laser beam within the exposure apparatus to manufacture an electronic device. The laser apparatus includes a line narrowing module and an output coupling mirror, the line narrowing module includes a prism including a transmission surface through which a laser beam is transmitted, a bottom surface in contact with the transmission surface, and a top surface facing the bottom surface, and a holder holding the prism on the bottom surface, and the output coupling mirror includes a partial reflective film having a reflectance changing in a direction in which the bottom surface and the top surface face each other.

### BRIEF DESCRIPTION OF THE DRAWINGS

Some embodiments of the present disclosure will be described below, by way of example only, with reference to the accompanying drawings.

FIG. 1 is a diagram schematically illustrating a configuration of a laser apparatus according to a comparative example.

FIG. 2 is a diagram schematically illustrating the configuration of the laser apparatus according to the comparative example.

FIG. 3 is a diagram schematically illustrating a configuration of a prism.

FIG. 4 is a diagram illustrating an example of a temporal change of PointingV during a continuous operation of the laser apparatus according to the comparative example.

FIG. 5 is a diagram schematically illustrating an example of a temperature gradient generated in a magnifying optical system in the comparative example.

FIG. 6 is a diagram illustrating a temperature coefficient of refractive indexes of substances making up the magnifying optical system.

FIG. 7 is a diagram schematically illustrating a configuration of a laser apparatus according to a first embodiment.

FIG. 8 is a diagram schematically illustrating a configuration of an output coupling mirror according to the first embodiment.

FIG. 9 is a diagram illustrating an example of a relation between an internal load and a reflectance of the output coupling mirror.

FIG. 10 is a diagram schematically illustrating an example of a temperature gradient generated in a magnifying optical system in the first embodiment.

FIG. 11 is a diagram illustrating an example of a temporal change of PointingV during a continuous operation of the laser apparatus according to the first embodiment.

FIG. 12 is a diagram schematically illustrating V direction dependence of various characteristics of an optical resonator according to the first embodiment.

FIG. 13 is a diagram illustrating a relation between extraction efficiency and the reflectance of the output coupling mirror in a case where g₀/α is 20.

FIG. 14 is a diagram illustrating a relation between the extraction efficiency and the reflectance of the output coupling mirror in a case where g₀/α is 10.

FIG. 15 is a diagram schematically illustrating V direction dependence of various characteristics of an optical resonator according to a first modification.

FIG. 16 is a diagram illustrating an example in which a first partial reflective film and a second partial reflective film are provided such that a boundary passes through a +V direction side of a center of an irradiation area.

FIG. 17 is a diagram illustrating an example in which the first partial reflective film and the second partial reflective film are provided such that the boundary passes through a −V direction side of the center of the irradiation area.

FIG. 18 is a diagram schematically illustrating the V direction dependence of various characteristics of the optical resonator when the boundary is set as illustrated in FIG. 16.

FIG. 19 is a diagram schematically illustrating the V direction dependence of various characteristics of the optical resonator when the boundary is set as illustrated in FIG. 17.

FIG. 20 is a diagram schematically illustrating an example of a relation between a change amount of PointingV and a boundary position.

FIG. 21 is a diagram schematically illustrating a configuration of an output coupling mirror according to a second embodiment.

FIG. 22 is a diagram schematically illustrating V direction dependence of various characteristics of an optical resonator according to the second embodiment.

FIG. 23 is a diagram illustrating an example of a temporal change of PointingV during a continuous operation of a laser apparatus according to the second embodiment.

FIG. 24 is a diagram schematically illustrating a configuration example of an exposure apparatus.

### DESCRIPTION OF EMBODIMENTS

### Contents

1. Comparative Example
   1.1 Configuration
   1.2 Operation
   1.3 Problem
2. First Embodiment
   2.1 Configuration
   2.2 Operation
   2.3 Effect
3. Modification of First Embodiment
   3.1 First Modification
   3.2 Second Modification
4. Second Embodiment
   4.1 Configuration
   4.2 Operation
   4.3 Effect
5. Electronic Device Manufacturing Method

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Comparative Example

First, a comparative example of the present disclosure will be described. The comparative example of the present disclosure is an example recognized by the applicant as known only by the applicant, and is not a publicly known example admitted by the applicant.

### 1.1 Configuration

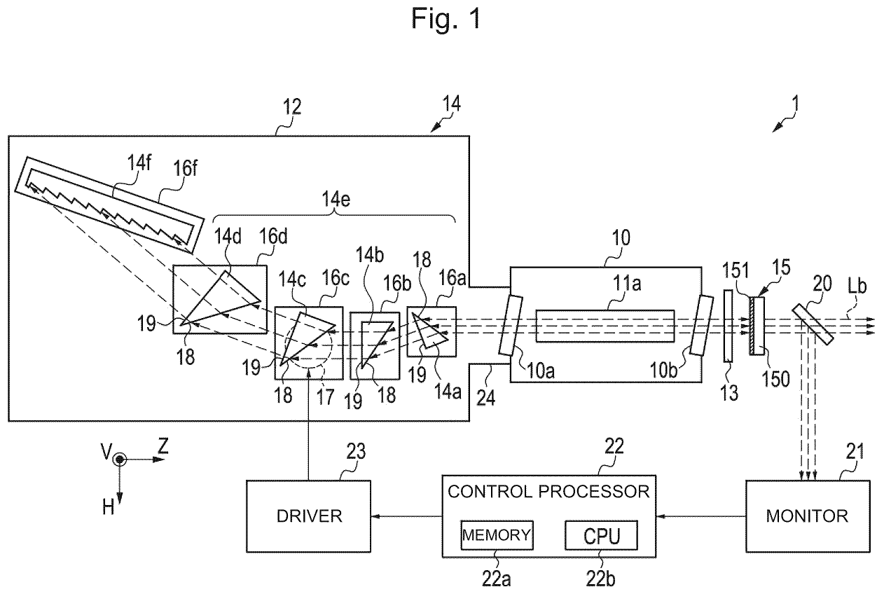

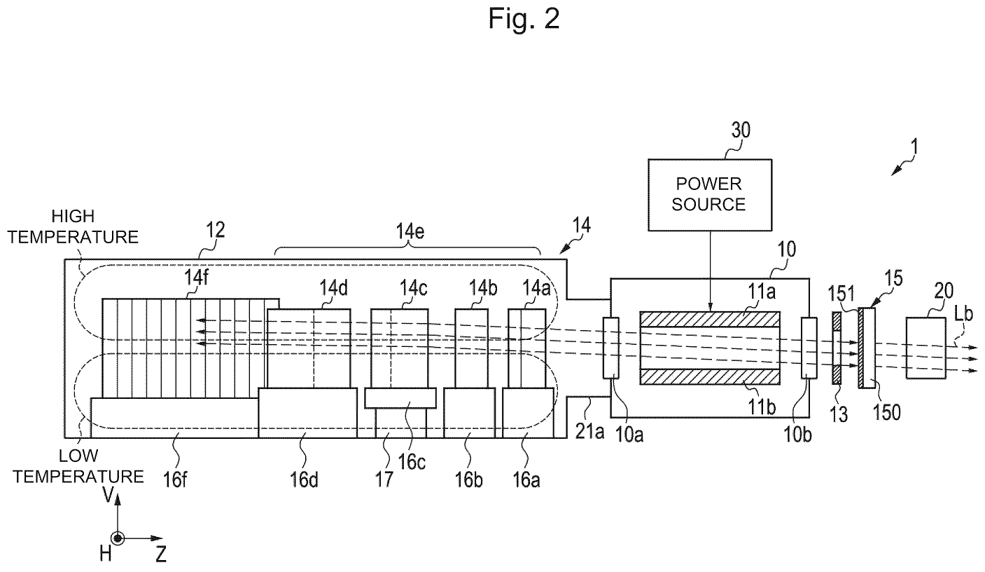

FIG. 1 and FIG. 2 schematically illustrate a configuration of a laser apparatus 1 according to the comparative example. The laser apparatus 1 is an excimer laser apparatus that outputs an ultraviolet laser beam Lb.

The laser apparatus 1 includes a laser chamber 10, a pair of discharge electrodes 11a and 11b, a line narrowing module 14, and an output coupling mirror 15. The laser apparatus 1 further includes a beam splitter 20, a monitor 21 capable of measuring a wavelength and energy intensity of the laser beam Lb, a control processor 22, and a driver 23. The line narrowing module 14 and the output coupling mirror 15 form an optical resonator. The laser chamber 10 is disposed in an optical path of the optical resonator.

In the present disclosure, a traveling direction of the laser beam Lb output through the output coupling mirror 15 is defined as a Z direction. A direction of discharge that occurs between the pair of discharge electrodes 11a and 11b is defined as a V direction. The Z direction and the V direction are orthogonal to each other. A direction orthogonal to the Z direction and the V direction is defined as an H direction. FIG. 1 illustrates the laser apparatus 1 viewed from the V direction. FIG. 2 illustrates the laser apparatus 1 viewed from the H direction. The V direction is an example of a “first direction” according to technology of the present disclosure. The H direction is an example of a “second direction” according to the technology of the present disclosure.

The laser chamber 10 is filled with a laser gas containing a component of a laser medium. The laser gas includes, for example, an argon gas or a krypton gas as a rare gas, a fluorine gas as a halogen gas, and a neon gas as a buffer gas, or the like. Windows 10a and 10b are provided on both ends of the laser chamber 10.

The discharge electrodes 11a and 11b are disposed in the laser chamber 10. The discharge electrode 11a is connected to a power source 30, and the discharge electrode 11b is provided with a grounding potential.

As illustrated in FIG. 1, the windows 10a and 10b are disposed such that planes of incidence of the laser beam Lb on the windows are substantially parallel to an HZ plane, and an incident angle of the laser beam Lb is substantially Brewster's angle.

The line narrowing module 14 includes a magnifying optical system 14e, a grating 14f, and a housing 12. The magnifying optical system 14e includes four prisms 14a-14d.

Each of the prisms 14a-14d is formed of crystals of calcium fluoride. Each of the prisms 14a-14d includes two transmission surfaces 18 and 19 through which the laser beam Lb is transmitted. The transmission surfaces 18 and 19 are parallel to the V direction.

Each of the prisms 14a-14d is disposed such that a traveling direction of the laser beam Lb passing through the transmission surface 18 is non-perpendicular to the transmission surface 18, and a traveling direction of the laser beam Lb passing through the transmission surface 19 is substantially perpendicular to the transmission surface 19. The laser beam Lb is refracted on the transmission surface 18, and the laser beam Lb travels substantially straight on the transmission surface 19. The transmission surface 18 is coated with a film that suppresses reflection of P-polarized components of the laser beam Lb. The transmission surface 19 is coated with a film that suppresses reflection of the laser beam Lb.

By setting the volume of each of the prisms 14a-14d according to a beam width of the passing laser beam Lb, usage of a material can be reduced. When two or more of the prisms 14a-14d are equal in volume, components may be shared as long as the same material is used for the components. The magnifying optical system 14e may include at least one prism.

The housing 12 houses the magnifying optical system 14e and the grating 14f. The prism 14a is held by a holder 16a, the prism 14b is held by a holder 16b, the prism 14c is held by a holder 16c, the prism 14d is held by a holder 16d, and the grating 14f is held by a holder 16f. The holder 16c includes a rotating mechanism 17 driven by the driver 23 to rotate the prism 14c about an axis parallel to the V direction.

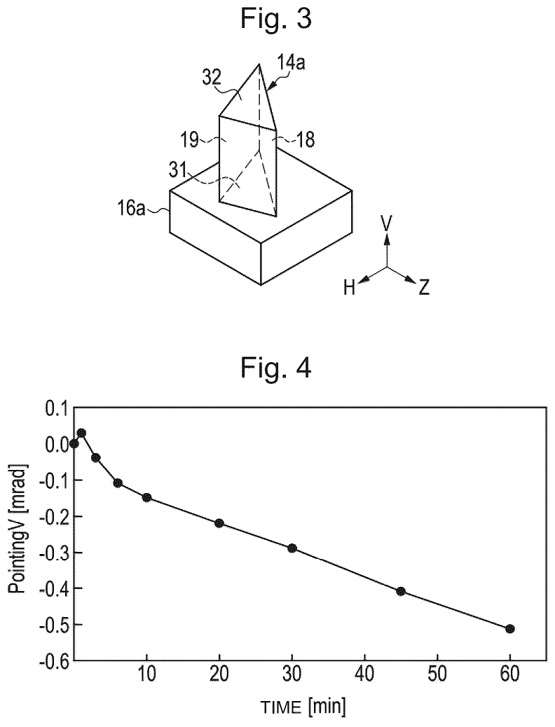

Specifically, as illustrated in FIG. 3, the prism 14a is a triangular prism including the transmission surfaces 18 and 19, a bottom surface 31 in contact with the transmission surfaces 18 and 19, and a top surface 32 facing the bottom surface 31. The holder 16a holds the prism 14a at the bottom surface 31. The top surface 32 is pressed by an unillustrated fixing member. The other prisms 14b-14d have the same configuration as the prism 14a. A direction in which the bottom surface 31 and the top surface 32 face each other corresponds to the V direction. In particular, a direction from the bottom surface 31 toward the top surface 32 is referred to as a “+V direction”, and a direction from the top surface 32 toward the bottom surface 31 is referred to as a “−V direction”.

The grating 14f is an echelle grating which includes a high reflectance material on the surface and in which a large number of grooves are provided at predetermined intervals.

The housing 12 is connected to the laser chamber 10 by an optical path pipe 24. An inside of the optical path pipe 24 and an inside of the housing 12 communicate with each other. An inert gas such as a nitrogen gas is introduced into the inside of the housing 12 and the inside of the optical path pipe 24 from an unillustrated inert gas introduction pipe, and is discharged from an unillustrated inert gas discharge pipe. In this way, the inert gas is purged into the housing 12 and into the optical path pipe 24.

The output coupling mirror 15 is a partial reflective mirror formed by coating a partial reflective film 151 on a surface of a substrate 150 on a side of the window 10b. The substrate 150 is a glass substrate made of calcium fluoride, for example. The partial reflective film 151 is coated such that a reflectance of the output coupling mirror 15 is uniform within the surface, and the reflectance is, for example, 10%.

Further, a slit 13 is disposed between the window 10b and the output coupling mirror 15. The slit 13 has a slit width narrower than a distance between the pair of discharge electrodes 11a and 11b, and limits the beam width of the laser beam Lb output through the window 10b of the laser chamber 10 in a discharge direction.

The beam splitter 20 is disposed in an optical path of the laser beam Lb output through the output coupling mirror 15. A partial reflective film is coated on one surface of the beam splitter 20. The monitor 21 is disposed in an optical path of the laser beam Lb reflected by the beam splitter 20. The monitor 21 includes an unillustrated energy sensor, a spectrometer such as an etalon, and an image sensor.

The control processor 22 is, for example, a processing device including a memory 22a in which a control program is stored, and a CPU (central processing unit) 22b which executes the control program. The control processor 22 is specifically configured or programmed to execute various kinds of processing included in the present disclosure.

### 1.2 Operation

Next, an operation of the laser apparatus 1 according to the comparative example will be described. When a high voltage is applied between the discharge electrodes 11a and 11b by the power source 30, discharge occurs between the discharge electrodes 11a and 11b. The laser medium in the laser chamber 10 is excited by energy of the discharge, and shifts to a high energy level. When the excited laser medium shifts to a low energy level, the laser beam Lb having a wavelength corresponding to a difference between the high energy level and the low energy level is discharged.

The laser beam Lb generated in the laser chamber 10 is output to an outside of the laser chamber 10 through the windows 10a and 10b. The laser beam Lb output through the window 10a of the laser chamber 10 is enlarged in a beam width in the H direction by being refracted in a plane parallel to the HZ plane by the magnifying optical system 14e, and enters the grating 14f.

The laser beam Lb that has entered the grating 14f from the magnifying optical system 14e is reflected at the grating 14f, and is diffracted in a direction according to a wavelength. As a result, the laser beam Lb reflected at the grating 14f is dispersed in the plane parallel to the HZ plane. The grating 14f is disposed in Littrow arrangement such that an incident angle of the laser beam Lb entering the grating 14f from the magnifying optical system 14e coincides with a diffracting angle of diffracted light having a desired wavelength. As a result, the laser beam Lb near the desired wavelength returns to the laser chamber 10 via the magnifying optical system 14e.

The magnifying optical system 14e reduces the beam width of the laser beam Lb that has entered from the grating 14f in the H direction, and returns the laser beam Lb into the laser chamber 10 through the window 10a.

The output coupling mirror 15 transmits and outputs a part of the laser beam Lb that is output through the window 10b of the laser chamber 10 and has the beam width limited by the slit 13, and reflects the other part back into the laser chamber 10.

In this way, the laser beam Lb output from the laser chamber 10 reciprocates between the line narrowing module 14 and the output coupling mirror 15, and is amplified every time it passes through a discharge space between the discharge electrodes 11a and 11b. The laser beam Lb is line-narrowed every time it is turned back in the line narrowing module 14. Further, polarization components in the H direction are selected by disposition of the windows 10a and 10b and coating of the prisms 14a-14d described above. In such a manner, the amplified laser beam Lb is output through the output coupling mirror 15. The laser beam Lb has a wavelength in a vacuum ultraviolet region.

The beam splitter 20 transmits a part of the laser beam Lb output through the output coupling mirror 15 at a high transmittance and reflects the other part. The laser beam Lb that has transmitted through the beam splitter 20 enters an exposure apparatus.

The laser beam Lb reflected by the beam splitter 20 enters the spectrometer included in the monitor 21. The spectrometer forms interference fringes of the laser beam Lb on a light receiving surface of the image sensor included in the monitor 21. The image sensor generates image data of the interference fringes, and transmits the generated image data to the control processor 22.

The control processor 22 receives target wavelength data representing a target wavelength from a control unit or the like of the exposure apparatus. Further, the control processor 22 receives the image data from the monitor 21, and calculates the wavelength of the laser beam Lb based on the received image data. The control processor 22 transmits a control signal to the driver 23 based on the target wavelength data and the calculated wavelength of the laser beam Lb. The driver 23 transmits a drive signal to the rotating mechanism 17 based on the control signal.

The rotating mechanism 17 rotates the holder 16c together with the prism 14c in response to the drive signal from the driver 23. By rotating the prism 14c, the incident angle of the laser beam Lb on the grating 14f is changed and the wavelength is adjusted. In the present comparative example, the prism 14c is rotatable for wavelength control, but without being limited thereto, any of the prisms 14a-14d may be rotatable.

### 1.3 Problem

When the laser apparatus 1 according to the comparative example is continuously operated, the traveling direction of the laser beam Lb reflected at the grating 14f and output from the line narrowing module 14 via the magnifying optical system 14e may vary. In the present disclosure, the traveling direction of the laser beam Lb is referred to as pointing, and an angle of the pointing in the V direction with respect to a reference direction is defined as “PointingV”. A unit of PointingV is mrad. The reference direction is, for example, the Z direction.

FIG. 4 illustrates an example of a temporal change of the PointingV during a continuous operation of the laser apparatus 1 according to the comparative example. According to FIG. 4, the traveling direction of the laser beam Lb output from the line narrowing module 14 changes in the −V direction as time passes from start of the continuous operation.

Referring back to FIG. 2, probable causes for changing of the PointingV will be described. When the laser apparatus 1 is continuously operated, the magnifying optical system 14e absorbs a part of the energy of the laser beam Lb, resulting in a temperature increase. As a result, the temperature inside the magnifying optical system 14e becomes non-uniform, which generates a gradient. For example, the temperature at portions of the prisms 14a-14d that are far from the respective holders 16a-16d becomes high, while the temperature at portions of prisms 14a-14d that are close to the respective holders 16a-16d becomes low.

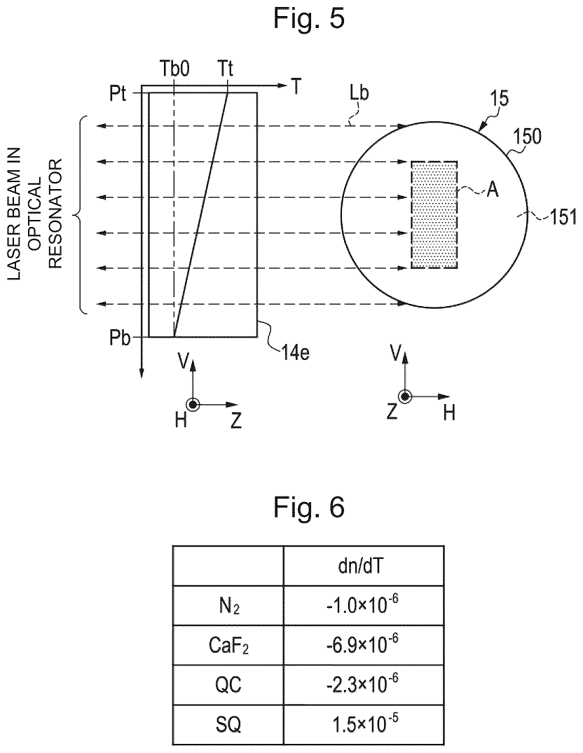

FIG. 5 schematically illustrates an example of a temperature gradient generated in the magnifying optical system 14e in the comparative example. In FIG. 5, Pt indicates a contact position of the prisms 14a-14d and the fixing member in the V direction, and Pb indicates a contact position of the prisms 14a-14d and the holders 16a-16d in the V direction. In addition, Tt indicates a highest temperature on a contact surface of the prisms 14a-14d with the fixing member, and Tb0 indicates a highest temperature on a contact surface of the prisms 14a-14d with the holders 16a-16d. In the present disclosure, the temperature gradient refers to a change rate of a temperature T in the V direction. Further, A indicates an area to be irradiated with the laser beam Lb in the output coupling mirror 15.

One possible cause for such a temperature gradient is that thermal energy of the part of the prisms 14a-14d close to the holders 16a-16d is lost due to heat conduction to the holders 16a-16d. Another possible cause is that heat conduction is generated from the fixing member heated by scattered light of the laser beam Lb to the prisms 14a-14d and causes a temperature increase at the parts of the prisms 14a-14d far from the holders 16a-16d.

A refractive index of crystals of calcium fluoride forming the prisms 14a-14d is temperature dependent, and the refractive index decreases as the temperature increases. In general, since a speed of light passing through the medium increases as the refractive index decreases, when the traveling direction of the light intersects with a direction of the temperature gradient, a wavefront of the light is inclined toward a lower temperature side. Therefore, as illustrated in FIG. 2, it is expected that the traveling direction of the laser beam Lb changes in a low temperature direction, that is, in the −V direction. When an absolute value of the PointingV increases with time and exceeds a threshold value, due to vignetting or the like of the laser beam Lb occurring in an optical system of the exposure apparatus, decrease in throughput, decrease in imaging performance, and the like may occur.

A substance making up the prisms 14a-14d needs to be highly transparent to the laser beam Lb. In addition to the calcium fluoride CaF₂ described above, quartz QC or synthetic quartz SQ are assumed as the substance making up the prisms 14a-14d. Further, substances making up the magnifying optical system 14e include, in addition to the substance making up the prisms 14a-14d, a nitrogen gas N₂ as an inert gas present on the optical path.

FIG. 6 illustrates temperature coefficients dn/dT of refractive indexes of the substances making up the magnifying optical system 14e. The temperature coefficient dn/dT is a change amount of a refractive index n of light having a wavelength of 248.4 nm when the temperature T changes by 1° C. According to FIG. 6, the crystal QC has an absolute value of the thermal coefficient dn/dT lower than that of the calcium fluoride CaF₂. In addition, the crystal QC and the calcium fluoride CaF₂ both have a negative temperature coefficient dn/dT, whereas the synthetic quartz SQ has a positive temperature coefficient dn/dT.

Therefore, it is conceivable to suppress changing of the PointingV by making up the magnifying optical system 14e with a combination of the calcium fluoride CaF₂ having a negative temperature coefficient dn/dT and the synthetic quartz SQ having a positive temperature coefficient dn/dT. However, since the quartz QC, the synthetic quartz SQ, and the like are less resistant to ultraviolet light, lifetime of the line narrowing module 14 is reduced when the magnifying optical system 14e is made up as described above.

Further, it is conceivable to suppress changing of the PointingV by providing a temperature controller so as to suppress the temperature gradient in the V direction in the housing 12, which, however, leads to a cost increase.

Therefore, an object of the present disclosure is to suppress changing of the PointingV by suppressing the temperature gradient in the V direction of the magnifying optical system 14e without causing a cost increase.

### 2. First Embodiment

### 2.1 Configuration

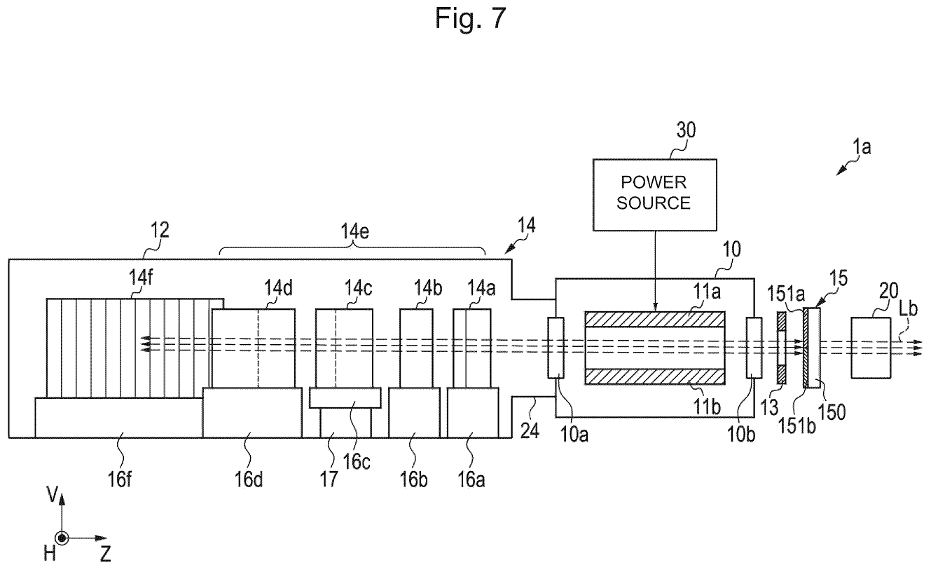

FIG. 7 schematically illustrates a configuration of a laser apparatus 1a according to a first embodiment of the present disclosure. FIG. 7 illustrates the laser apparatus 1a viewed from the H direction. An illustration of the laser apparatus 1a viewed from the V direction is omitted. The laser apparatus 1a has the same configuration as the laser apparatus 1 according to the comparative example except that a configuration of the output coupling mirror 15 is different.

In the comparative example, for the output coupling mirror 15, the partial reflective film 151 having a uniform reflectance is provided on the surface of the substrate 150 on the side of the window 10b. On the other hand, in the present embodiment, for the output coupling mirror 15, a first partial reflective film 151a having a first reflectance R1 and a second partial reflective film 151b having a second reflectance R2 higher than the first reflectance R1 are provided on the surface of the substrate 150 on the side of the window 10b. That is, the first partial reflective film 151a and the second partial reflective film 151b form a partial reflective film having a reflectance changing in a direction in which the bottom surface 31 and the top surface 32 face each other.

The substrate 150 is, for example, a glass substrate made of calcium fluoride. Each of the first partial reflective film 151a and the second partial reflective film 151b is a dielectric multilayer film in which a predetermined reflectance is realized by alternately laminating a dielectric material having a high refractive index and a dielectric material having a low refractive index. As a high refractive index material, for example, any one of lanthanum fluoride (LaF₃), gadolinium fluoride (GdF₃), and alumina (Al₂O₃) can be selected. As a low refractive index material, for example, any one of aluminum fluoride (AlF₃), magnesium fluoride (MgF₂), and silicon oxide (SiO₂) can be selected.

In the present embodiment, similarly to the comparative example, the prisms 14a-14d are formed of the calcium fluoride CaF₂ having the negative thermal coefficient dn/dT.

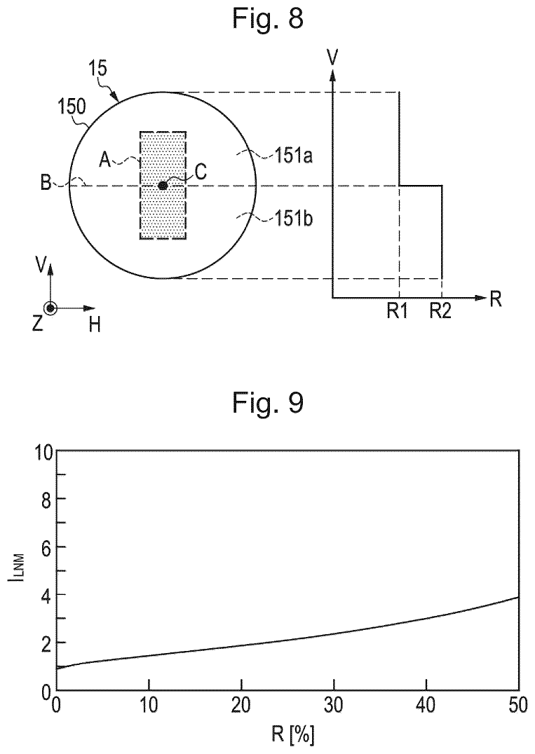

FIG. 8 schematically illustrates the configuration of the output coupling mirror 15 according to the first embodiment. FIG. 8 illustrates the output coupling mirror 15 viewed from the Z direction and position dependence of a reflectance R of the output coupling mirror 15. The first partial reflective film 151a and the second partial reflective film 151b are adjacent to each other in the V direction, and a boundary B is present between them. The boundary B extends linearly in the H direction. In addition, the boundary B passes through an irradiation area A of the laser beam Lb. In the present embodiment, the irradiation area A is an area to be irradiated with the laser beam Lb when the first partial reflective film 151a is provided on the entire surface of the output coupling mirror 15 on the side of the window 10b.

In the present embodiment, the boundary B passes through a center C of the irradiation area A. The first partial reflective film 151a is provided on a +V direction side with respect to the boundary B, and the second partial reflective film 151b is provided on a −V direction side. That is, the reflectance R of the output coupling mirror 15 changes at the boundary B, and is relatively higher on the −V direction side of the boundary B than on the +V direction side.

In the present embodiment, it is expected that a temperature gradient in which a temperature on the +V direction side of the magnifying optical system 14e is high and a temperature on the −V direction side is low is generated during a continuous operation of the laser apparatus 1a. Based on this expectation, the first partial reflective film 151a and the second partial reflective film 151b are disposed such that the first partial reflective film 151a having a low reflectance is irradiated with the laser beam Lb that has passed through a high temperature side and the second partial reflective film 151b having a high reflectance is irradiated with the laser beam Lb that has passed through a low temperature side. When the expected temperature gradient is reversed, the second partial reflective film 151b is disposed on the +V direction side, and the first partial reflective film 151a is disposed on the −V direction side.

### 2.2 Operation

An operation of the laser apparatus 1a according to the present embodiment is the same as that of the comparative example except that an action of the output coupling mirror 15 is different. Hereinafter, the action of the output coupling mirror 15 according to the present embodiment will be described.

In an optical resonator of the laser apparatus 1a according to the present embodiment, similarly to the comparative example, reflection by the output coupling mirror 15 causes one laser beam Lb to pass through the high temperature side of the magnifying optical system 14e and the other laser beam Lb to pass through the low temperature side. Since the laser beam Lb passing through the high temperature side is reflected by the first partial reflective film 151a having the low reflectance, the light intensity is lower than the light intensity of the laser beam Lb on the low temperature side. Conversely, since the laser beam Lb passing through the low temperature side is reflected by the second partial reflective film 151b having the high reflectance, the light intensity is higher than the light intensity of the laser beam Lb on the high temperature side.

While a temperature of the magnifying optical system 14e increases through absorption of the laser beam Lb, in the present embodiment, the temperature of the magnifying optical system 14e on the low temperature side rises more because the light intensity of the laser beam Lb on the low temperature side is relatively higher than that on the high temperature side. Thus, the temperature gradient in the V direction of the magnifying optical system 14e is suppressed. As a result, changing of the PointingV is suppressed.

Next, a relation between the reflectance R of the output coupling mirror 15 and a temperature increase of the magnifying optical system 14e will be described in detail. When the light intensity of the laser beam Lb reflected by the output coupling mirror 15 is within a range of the light intensity with which stimulated emission light is proportionally generated in the optical resonator, it is conceivable that the laser beam Lb reflected by the output coupling mirror 15 imparts energy in the optical resonator. Hereinafter, the energy imparted in the optical resonator by the laser beam Lb reflected by the output coupling mirror 15 will be referred to as an internal load.

When the light intensity of the laser beam Lb output through the output coupling mirror 15 is Iₒᵤₜ and a reflectance of the line narrowing module 14 is R_{LNM}, a relation between an internal load I_{LNM} in the line narrowing module 14 and the reflectance R of the output coupling mirror 15 can be expressed by the following equation (1) based on modeling of the optical resonator.

$$\begin{matrix}[ Expression 1 ] & \\ {I}_{LNM} = \frac{{I}_{out}}{1 - R} ( \sqrt{R / {R}_{LNM}} + \sqrt{R \times {R}_{LNM}} ) & ( 1 )\end{matrix}$$

FIG. 9 illustrates an example of the relation between the internal load I_{LNM} and the reflectance R of the output coupling mirror 15. The internal load I_{LNM} illustrated in FIG. 9 is a value normalized by the light intensity Iₒᵤₜ in the equation (1) with R_{LNM} being 0.8. According to FIG. 9, it can be recognized that the internal load I_{LNM} increases as the reflectance R of the output coupling mirror 15 increases, and consequently an absorbed amount of the laser beam Lb increases in the magnifying optical system 14e.

In the present embodiment, since the reflectance R of the output coupling mirror 15 is relatively higher on the −V direction side, the internal load I_{LNM} on the −V direction side increases, and the temperature of the magnifying optical system 14e on the low temperature side rises more. For example, in a case where R1 is 10% and R2 is 20%, the internal load I_{LNM} on the low temperature side is about 1.3 times the internal load I_{LNM} on the high temperature side.

### 2.3 Effect

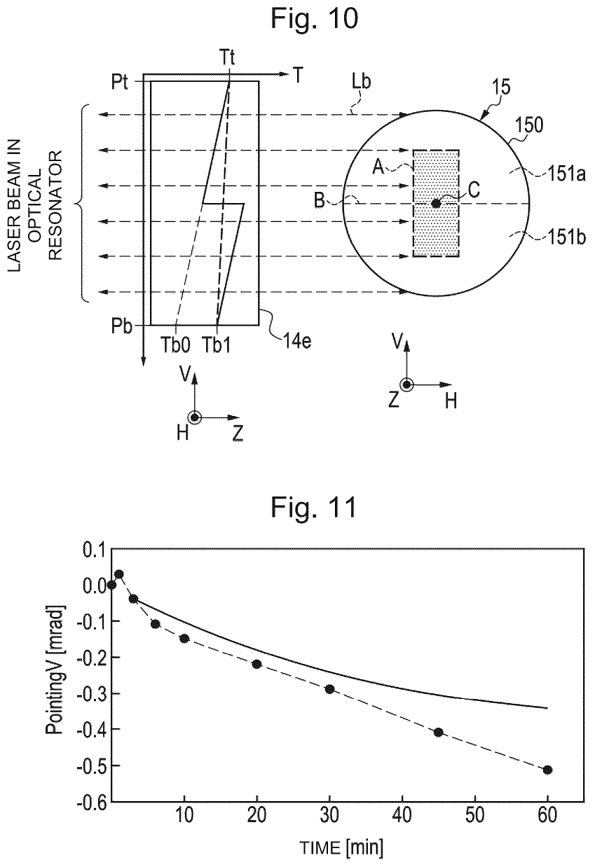

FIG. 10 schematically illustrates an example of a temperature gradient generated in the magnifying optical system 14e in the first embodiment. In the present embodiment, as described above, since the light intensity of the laser beam Lb on the low temperature side is made relatively higher in the optical resonator, the temperature of the magnifying optical system 14e on the low temperature side relatively increases. Thus, as illustrated in FIG. 10, a temperature boundary corresponding to the boundary B between the first partial reflective film 151a and the second partial reflective film 151b is generated in the temperature gradient in the V direction generated in the magnifying optical system 14e, and a temperature at a position Pb of the magnifying optical system 14e increases from Tb0 to Tb1 in the comparative example. In practice, the temperature gradient becomes a smoother shape due to heat conduction or the like, but for the sake of simplicity of explanation, a schematic shape is illustrated so that influence of the heat conduction or the like is eliminated.

As a result, since a temperature change from Tt to Tb1, which is a substantial temperature gradient, is lower than a temperature change from Tt to Tb0 in the comparative example, as illustrated in FIG. 11, changing of the PointingV is suppressed. In FIG. 11, a solid line represents an example of changing of the PointingV in the present embodiment, and a broken line represents an example of changing of the PointingV in the comparative example.

Therefore, according to the present embodiment, it is possible to suppress changing of the PointingV by suppressing the temperature gradient in the V direction of the magnifying optical system 14e without causing a cost increase.

### 3. Modification of First Embodiment

Next, various modifications of the first embodiment will be described.

### 3.1 First Modification

According to the first embodiment, changing of the PointingV can be suppressed, but symmetry in the V direction of the light intensity Iₒᵤₜ of the laser beam Lb output through the output coupling mirror 15 may be deteriorated.

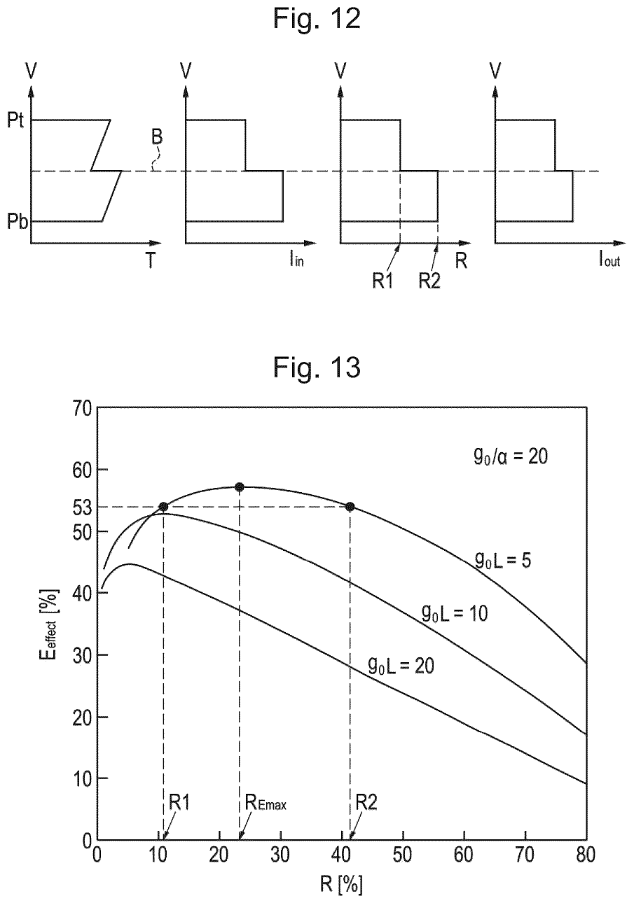

FIG. 12 schematically illustrates V direction dependence of various characteristics of the optical resonator according to the first embodiment. FIG. 12 illustrates the V direction dependence of the temperature T of the magnifying optical system 14e, light intensity Iᵢₙ of the laser beam Lb in the optical resonator, the reflectance R of the output coupling mirror 15, and the light intensity Iₒᵤₜ of the laser beam Lb output through the output coupling mirror 15. In this way, in the first embodiment, asymmetry may occur in the light intensity Iₒᵤₜ with respect to the boundary B.

In this modification, changing of the PointingV is suppressed, and the asymmetry of the light intensity Iₒᵤₜ is suppressed.

The laser apparatus 1a according to the present modification is the same as that of the first embodiment except that the first reflectance R1 of the first partial reflective film 151a and the second reflectance R2 of the second partial reflective film 151b are determined so as to suppress the asymmetry of the light intensity Iₒᵤₜ.

In the present modification, the first reflectance R1 and the second reflectance R2 are determined based on extraction efficiency E_{effect} of the laser beam Lb from the output coupling mirror 15. The extraction efficiency E_{effect} is an index indicating how efficiently an optical resonator can extract output of the laser beam Lb.

A relation between the extraction efficiency E_{effect} and the reflectance R of the output coupling mirror 15 is expressed by the following equation (2). In addition, the following equation (2) can be transformed into the following equation (3). Here, g₀ represents a small signal gain coefficient, α represents an unsaturated absorption coefficient, L represents a gain length, and Iₛ represents saturation intensity.

$$\begin{matrix}[ Expression 2 ] & \\ {E}_{effect} = \frac{{I}_{o u t}}{{g}_{0} {LI}_{s}} = \frac{2 ( 1 - \sqrt{R} )}{( 1 + \sqrt{R} )} \{ \frac{1}{α L - \frac{1}{2} ln R} - \frac{1}{{g}_{0} L} \} & ( 2 )\end{matrix}$$

$$\begin{matrix}[ Expression 3 ] & \\ {E}_{effect} = \frac{2 ( 1 - \sqrt{R} )}{( 1 + \sqrt{R} )} \{ \frac{{g}_{0} / α}{{g}_{0} L - ( \frac{1}{2} ln R ) {g}_{0} / α} - \frac{1}{{g}_{0} L} \} & ( 3 )\end{matrix}$$

According to the equation (3), the relation between the extraction efficiency E_{effect} and the reflectance R of the output coupling mirror 15 depends on a ratio g₀/α between the small signal gain coefficient g₀ and the unsaturated absorption coefficient α and a product g₀L of the small signal gain coefficient g₀ and the gain length L. The gain length L is a value determined by a design value of a discharge length. The small signal gain coefficient g₀ is a value determined by a gas pressure of the laser gas, an applied voltage to the discharge electrode 11a, and the like. When the laser apparatus 1a is an excimer laser apparatus, the ratio g₀/α often takes a value in a range of 10 to 20, and the product g₀L often takes a value in a range of 5 to 20.

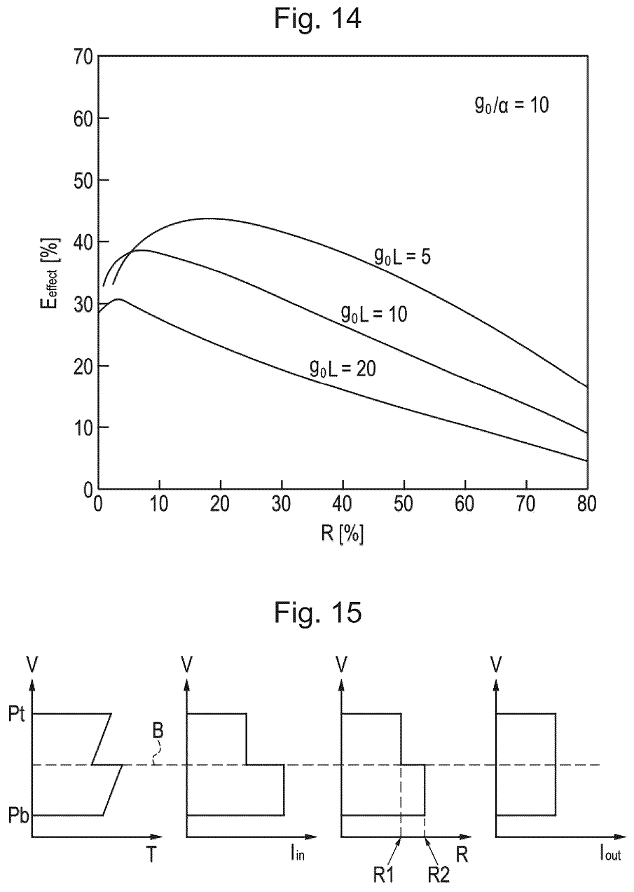

FIG. 13 illustrates a relation between the extraction efficiency E_{effect} and the reflectance R of the output coupling mirror 15 in a case where g₀/α is 20. FIG. 14 illustrates a relation between the extraction efficiency E_{effect} and the reflectance R of the output coupling mirror 15 in a case where g₀/α is 10. FIG. 13 and FIG. 14 illustrate three characteristic curves in cases where g₀L is 5, g₀L is 10, and g₀L is 20.

In the present modification, at a particular ratio g₀/α and product g₀L, two different reflectances R with the same extraction efficiency E_{effect} are determined as the first reflectance R1 and the second reflectance R2. FIG. 13 illustrates how the first reflectance R1 and the second reflectance R2 are determined. First, one characteristic curve is selected, and the reflectance R at which the extraction efficiency E_{effect} is maximized in the selected characteristic curve is specified as a reflectance R_{Emax}. Next, two reflectances R having substantially the same extraction efficiency E_{effect} are specified on the side where the reflectance R is higher and the side where the reflectance R is lower than the reflectance R_{Emax}, and the two specified reflectances R are determined as the first reflectance R1 and the second reflectance R2.

As illustrated in FIG. 13, when the characteristic curve in a case where g₀/α is 20 and g₀L is 5 is selected and 53% is selected as the extraction efficiency E_{effect}, the first reflectance R1 is about 10% and the second reflectance R2 is about 40%. In the case where g₀/α is 20 and g₀L is 10, the first reflectance R1 may be about 5% and the second reflectance R2 may be about 20%. Further, in the case where g₀/α is 20 and g₀L is 20, the first reflectance RI may be about 3% and the second reflectance R2 may be about 10%. For example, the extraction efficiency E_{effect} at the first reflectance R1 may be different from the extraction efficiency E_{effect} at the second reflectance R2 by ±5%.

An operation of the laser apparatus 1a according to the present modification is the same as that of the first embodiment except that the action of the output coupling mirror 15 is different. In the present modification, for the output coupling mirror 15, the first reflectance R1 and the second reflectance R2 are determined such that the extraction efficiency E_{effect} of the laser beam Lb becomes equal. Thus, the light intensity Iₒᵤₜ of the laser beam Lb transmitted through the first partial reflective film 151a and output through the output coupling mirror 15 becomes substantially equal to the light intensity Iₒᵤₜ of the laser beam Lb transmitted through the second partial reflective film 151b and output through the output coupling mirror 15. Preferably, the first reflectance R1 and the second reflectance R2 are determined such that the ratio of the two is between 90% and 110%.

FIG. 15 schematically illustrates V direction dependence of various characteristics of the optical resonator according to the first modification. FIG. 15 illustrates the V direction dependence of the temperature T of the magnifying optical system 14e, the light intensity Iᵢₙ of the laser beam Lb in the optical resonator, the reflectance R of the output coupling mirror 15, and the light intensity Iₒᵤₜ of the laser beam Lb output through the output coupling mirror 15. In this way, according to the present modification, the asymmetry of the light intensity Iₒᵤₜ with respect to the boundary B is suppressed. That is, according to the present modification, it is possible to suppress changing of the PointingV and to suppress the asymmetry of the light intensity Iₒᵤₜ.

### 3.2 Second Modification

In the first embodiment, the first partial reflective film 151a and the second partial reflective film 151b are provided such that the boundary B passes through the center C of the irradiation area A. On the other hand, in the present modification, the first partial reflective film 151a and the second partial reflective film 151b are provided such that the boundary B passes through a position other than the center C of the irradiation area A.

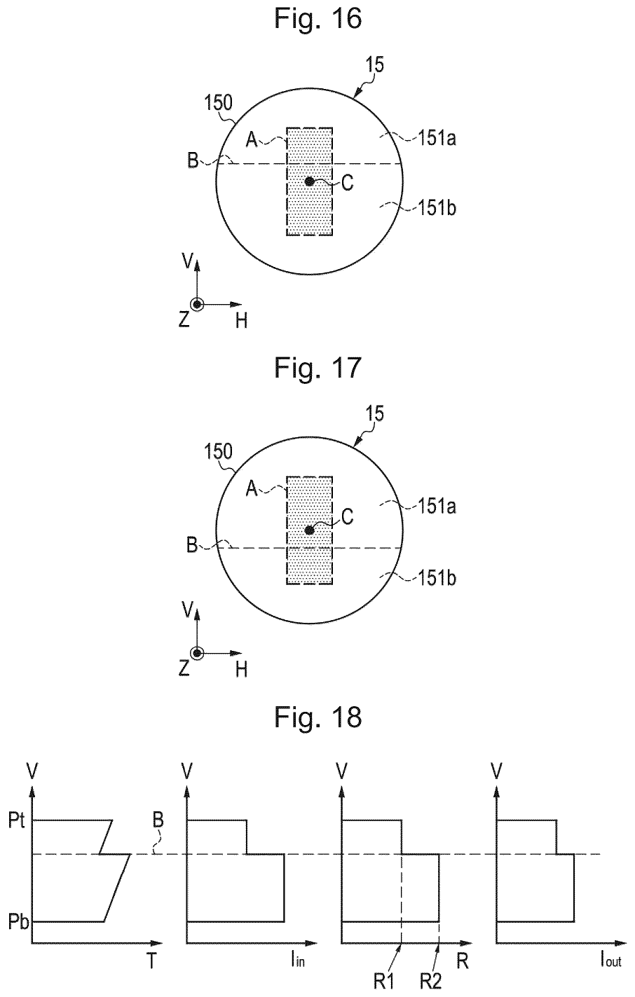

FIG. 16 illustrates an example in which the first partial reflective film 151a and the second partial reflective film 151b are provided such that the boundary B passes through a +V direction side of the center C of the irradiation area A. Specifically, FIG. 16 illustrates the example in which the first partial reflective film 151a and the second partial reflective film 151b are provided such that the boundary B passes through a dividing point on the +V direction side of the center C when the irradiation area A is divided into three in the V direction.

FIG. 17 illustrates an example in which the first partial reflective film 151a and the second partial reflective film 151b are provided such that the boundary B passes through a −V direction side of the center C of the irradiation area A. Specifically, FIG. 17 illustrates the example in which the first partial reflective film 151a and the second partial reflective film 151b are provided such that the boundary B passes through a dividing point on the −V direction side of the center C when the irradiation area A is divided into three in the V direction.

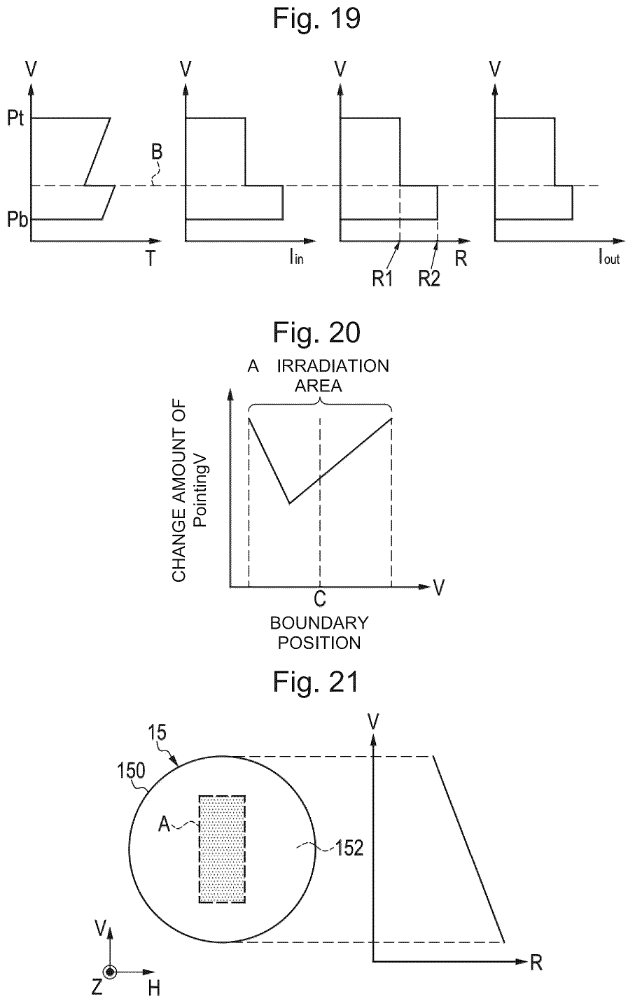

FIG. 18 schematically illustrates the V direction dependence of various characteristics of the optical resonator when the boundary B is set as illustrated in FIG. 16. FIG. 19 schematically illustrates the V direction dependence of various characteristics of the optical resonator when the boundary B is set as illustrated in FIG. 17.

A position of the boundary B is determined, for example, based on a change amount of the PointingV. Hereinafter, the position of the boundary B is referred to as a “boundary position”. Further, the change amount of the PointingV refers to an absolute value of an amount of changing of the PointingV when the laser apparatus 1a is continuously operated for a fixed period of time.

FIG. 20 schematically illustrates an example of a relation between the change amount of the PointingV and the border position. As illustrated in FIG. 20, the change amount of the PointingV is not necessarily minimal when the border position coincides with the center C of the irradiation area A. Therefore, it is preferable that the boundary position at which the change amount of the PointingV is minimal is obtained in advance, and the first partial reflective film 151a and the second partial reflective film 151b are formed based on the obtained boundary position. Thus, changing of the PointingV can be further suppressed.

Without being limited to one of the first modification and the second modification, both the first modification and the second modification may be applied to the first embodiment.

### 4. Second Embodiment

Next, the laser apparatus 1a according to a second embodiment will be described. The laser apparatus 1a according to the present embodiment differs from the first embodiment only in a configuration of the output coupling mirror 15.

### 4.1 Configuration

FIG. 21 schematically illustrates the configuration of the output coupling mirror 15 according to the second embodiment. FIG. 21 illustrates the output coupling mirror 15 viewed from the Z direction and the position dependence of the reflectance R of the output coupling mirror 15. In the present embodiment, a partial reflective film 152 in which the reflectance R continuously changes in the V direction is provided on the surface of the substrate 150 on the side of the window 10b. That is, the partial reflective film 152 forms a partial reflective film having a reflectance changing in the direction in which the bottom surface 31 and the top surface 32 face each other.

In the present embodiment, it is expected that the temperature gradient in which the temperature on the +V direction side of the magnifying optical system 14e is high and the temperature on the −V direction side is low is generated during a continuous operation of the laser apparatus 1a. Based on this expectation, in the present embodiment, the partial reflective film 152 is provided such that the reflectance R continuously increases at a fixed change rate in a direction toward the −V direction side. When the expected temperature gradient is reversed, the partial reflective film 152 is provided such that the reflectance R continuously increases at the fixed change rate in a direction toward the +V direction side. In either case, a change rate of the reflectance R may not be fixed. The partial reflective film 152 may be provided such that the reflectance R continuously and monotonically increases in the direction toward the +V direction side or the −V direction side according to the expected temperature gradient.

### 4.2 Operation

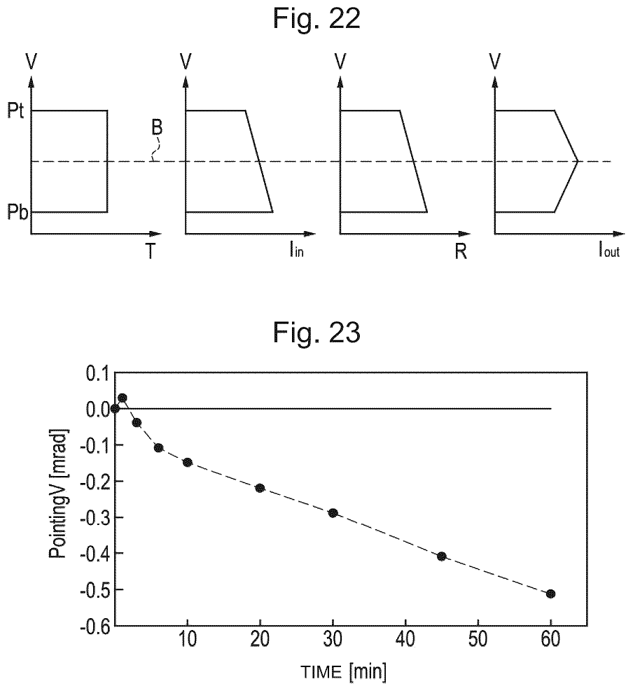

The operation of the laser apparatus 1a according to the present embodiment is the same as that of the comparative example except that the action of the output coupling mirror 15 is different. FIG. 22 schematically illustrates the V direction dependence of various characteristics of the optical resonator according to the second embodiment. As described above, by forming the partial reflective film 152 in which the reflectance R continuously changes according to the temperature gradient expected in the magnifying optical system 14e, the light intensity Iᵢₙ of the laser beam Lb in the optical resonator continuously changes in the V direction. Thus, the temperature gradient of the magnifying optical system 14e is cancelled.

### 4.3 Effect

According to the present embodiment, since the temperature gradient of the magnifying optical system 14e is cancelled, changing of the PointingV can be almost completely eliminated as illustrated in FIG. 23. In FIG. 23, a solid line represents an example of changing of the PointingV in the present embodiment, and a broken line represents an example of changing of the PointingV in the comparative example.

### 5. Electronic Device Manufacturing Method

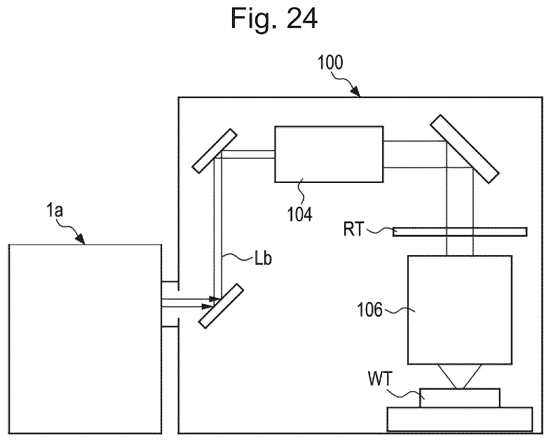

FIG. 24 schematically illustrates a configuration example of an exposure apparatus 100. The exposure apparatus 100 includes an illumination optical system 104 and a projection optical system 106. For example, the illumination optical system 104 illuminates a reticle pattern of an unillustrated reticle disposed on a reticle stage RT with the laser beam Lb that has entered from the laser apparatus 1a. The projection optical system 106 performs reduced projection of the laser beam Lb transmitted through the reticle, and forms an image on an unillustrated workpiece disposed on a workpiece table WT. The workpiece is a photosensitive substrate such as a semiconductor wafer on which photoresist is applied.

The exposure apparatus 100 synchronously translates the reticle stage RT and the workpiece table WT to expose the workpiece to the laser beam Lb reflecting the reticle pattern. After the reticle pattern is transferred onto the semiconductor wafer by an exposure process described above, a semiconductor device can be manufactured through a plurality of processes. The semiconductor device is an example of an “electronic device” in the present disclosure.

Note that the laser apparatus 1a may be used not only for manufacturing of an electronic device but also for laser processing such as drilling.

Further, while the laser apparatus including one laser chamber is illustrated as the laser apparatus 1a in the first and second embodiments, the laser apparatus 1a may be a two-stage laser apparatus including two laser chambers. In this case, the laser apparatus 1a includes an oscillation stage laser apparatus and an amplification stage laser apparatus that amplifies a laser beam discharged from the oscillation stage laser, and is, for example, an MOPO (Master Oscillator Power Oscillator).

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser apparatus comprising:
a line narrowing module; and
an output coupling mirror,
the line narrowing module including
a prism including a transmission surface through which a laser beam is transmitted, a bottom surface in contact with the transmission surface, and a top surface facing the bottom surface, and
a holder holding the prism on the bottom surface, and
the output coupling mirror including a partial reflective film having a reflectance changing in a direction in which the bottom surface and the top surface face each other.

2. The laser apparatus according to claim 1, wherein
the partial reflective film includes a first partial reflective film having a first reflectance and a second partial reflective film having a second reflectance, and
the first partial reflective film and the second partial reflective film are provided adjacent to each other in a first direction in which the bottom surface and the top surface face each other.

3. The laser apparatus according to claim 2, wherein
a boundary exists between the first partial reflective film and the second partial reflective film.

4. The laser apparatus according to claim 3, wherein
the boundary extends in a second direction orthogonal to the first direction.

5. The laser apparatus according to claim 4, wherein
the boundary passes through an irradiation area that is an area to be irradiated with the laser beam in the output coupling mirror.

6. The laser apparatus according to claim 5, wherein
the boundary passes through a center of the irradiation area.

7. The laser apparatus according to claim 6, wherein
the boundary passes through a top surface side of the center.

8. The laser apparatus according to claim 6, wherein
the boundary passes through a bottom surface side of the center.

9. The laser apparatus according to claim 2, wherein
the first partial reflective film is provided on a top surface side of the second partial reflective film, and
the first reflectance is lower than the second reflectance.

10. The laser apparatus according to claim 2, wherein
the first reflectance and the second reflectance are determined such that a ratio of light intensity of the laser beam transmitted through the first partial reflective film and output through the output coupling mirror and light intensity of the laser beam transmitted through the second partial reflective film and output through the output coupling mirror is within a range of 90% to 110%.

11. The laser apparatus according to claim 1, wherein
the reflectance continuously changes in a direction from the top surface to the bottom surface.

12. The laser apparatus according to claim 11, wherein
the reflectance increases in a direction from the top surface to the bottom surface.

13. The laser apparatus according to claim 1, wherein
the direction in which the bottom surface and the top surface face each other corresponds to a discharge direction.

14. The laser apparatus according to claim 1, wherein
the line narrowing module includes a magnifying optical system including at least one prism, and a grating where the laser beam enlarged in a beam width by the magnifying optical system enters.

15. An electronic device manufacturing method, comprising:
generating a laser beam with a laser apparatus, the laser apparatus including
a line narrowing module and an output coupling mirror,
the line narrowing module including
a prism including a transmission surface through which a laser beam is transmitted, a bottom surface in contact with the transmission surface, and a top surface facing the bottom surface, and
a holder holding the prism on the bottom surface, and
the output coupling mirror including a partial reflective film having a reflectance changing in a direction in which the bottom surface and the top surface face each other;
outputting the laser beam to an exposure apparatus; and
exposing a photosensitive substrate to the laser beam within the exposure apparatus to manufacture an electronic device.
